(19) United States
(12) Patent Application Publication
(10) Pub. No.: US 2025/0155481 A1
(43) Pub. Date: May 15, 2025

(54) MACHINE LEARNING SYSTEM AND METHODOLOGY FOR SIMULATING A MIXED ANALOG AND DIGITAL SYSTEM USING VARIOUS SETS OF PARAMETERS AND ESTIMATING THEIR RESPECTIVE POWER USAGES AND ACCURACIES

(71) Applicant: INVENSENSE, INC., San Jose, CA (US)

(72) Inventors: Remi Poncot, Grenoble (FR); Soufiane Atouani, Grenoble (FR)

(21) Appl. No.: 18/923,289

(22) Filed: Oct. 22, 2024

Related U.S. Application Data
(60) Provisional application No. 63/597,953, filed on Nov. 10, 2023.

(51) Int. Cl. G01R 21/133; H03M 1/12

(52) U.S. Cl. CPC G01R 21/133; H03M 1/12

(57) ABSTRACT

Disclosed embodiments provide a computer system and methodology for simulating operations of mixed analog and digital systems having various electronics components (for example, MEMS sensors, ADCs, and neural networks) for various sets of parameters, and selecting parameters for these components that would support an optimum pairing of power usage and accuracy in recognizing an activity or event.

### TECHNICAL FIELD

The subject disclosure relates to the field of consumer electronics devices, and specifically to devices having machine learning capabilities.

### PRIORITY CLAIM

The subject patent application claims priority to the provisional patent application entitled RESOLUTION AND SAMPLE RATE TUNABLE RECOGNITION MICROPHONE SYSTEM, having the application No. 63/597,953 and having the filing date of Nov. 10, 2023.

### BACKGROUND

Manufacturers of commercial electronics products such as wearables, toys, and audio speakers often build their products by using components such as sensors (e.g. MEMS sensors) and analog-to-digital converters (ADCs) that are made by someone else. Manufacturers of commercial electronics devices are generally not designers of MEMS sensors or ADCs. These manufacturers are thus limited in their skills and abilities to optimize power usages in their products. For example, these manufacturers may use by default high-power consuming MEMS microphone and high-power consuming audio ADC having 16 bits/16 khz resolution/sample rate in a system with their own custom-made recognition hardware (HW) solution. However, such high-quality high-power-consuming components, which are designed for complex telephony, are perhaps not needed for the event or activity that the product is designed to recognize. For example, if the product only needs to do key word spotting of words such as “hello” or “wake up” to perform an action, an ADC set to lower quality (e.g. 8 bits/8 khz), and thus having lower power usage, might work just fine. However, presently, the manufacturers of commercial electronics devices do not have good, easy, and scientifically reliable methodology or system available to them to assist with selection of components for optimum power usage.

### SUMMARY

The present invention discloses a computer system and methodology in which a first component receives as input a first set of parameters associated with a MEMS sensor configured to collect analog data associated with an event or an activity and possible values for each parameter of the first set of parameters. Also, a second component receives as input a second set of parameters associated with an analog-to-digital converter (ADC) configured to convert the analog data into digital data and possible values for each parameter of the second set of parameters. The second set of parameters includes sample rate and resolution. Also, a third component receives as input a third set of parameters associated with an integrated circuit chip including a feature extraction module and a machine learning model (MLM) configured to recognize the event or the activity by using the digital data and possible values for each parameter of the third set of parameters. In some examples, the third set of parameters can be divided into two sets of parameters, namely third and fourth sets, where the third set of parameters is associated with the feature extraction module and the fourth set of parameters is associated with the MLM. A simulation module estimates power usage level and accuracy level based on the three sets of parameters and the MLM. An identification module determines one of the maximum estimated accuracy-level for a given maximum power usage target or the minimum required power usage level for a given minimum accuracy target level. In this disclosure, the terms level and value are used interchangeably.

### BRIEF DESCRIPTION OF THE DRAWINGS

Various non-limiting embodiments are further described with reference to the accompanying drawings, in which:

FIG. 1 depicts an example embodiment of a system that is simulated by using systems and methodologies of the present invention;

FIG. 2 depicts an example embodiment of a power model;

FIG. 3 depicts an example methodology for simulating the power model;

FIG. 4 depicts another example methodology for simulating the power model;

FIG. 5 depicts an example list of parameters for a power model;

FIG. 6 depicts an example list of parameter values for a power model;

FIG. 7 depicts an example accuracy-power plot that can result from simulation or

the power model;

FIG. 8 depicts a sample computer system in which methodologies of the present invention can be implemented;

FIG. 9 depicts example accuracy-power pairs simulated by the simulation module;

FIG. 10 depicts an example interactive user interface; and

FIG. 11 depicts a functional block-diagram of an exemplary computing device suitable for practicing various non-limiting aspects described herein.

### DETAILED DESCRIPTION

While a brief overview is provided, certain aspects of the subject disclosure are described or depicted herein for the purposes of illustration and not limitation. Thus, variations of the disclosed embodiments as suggested by the disclosed apparatuses, systems, and methodologies are intended to be encompassed within the scope of the subject matter disclosed herein.

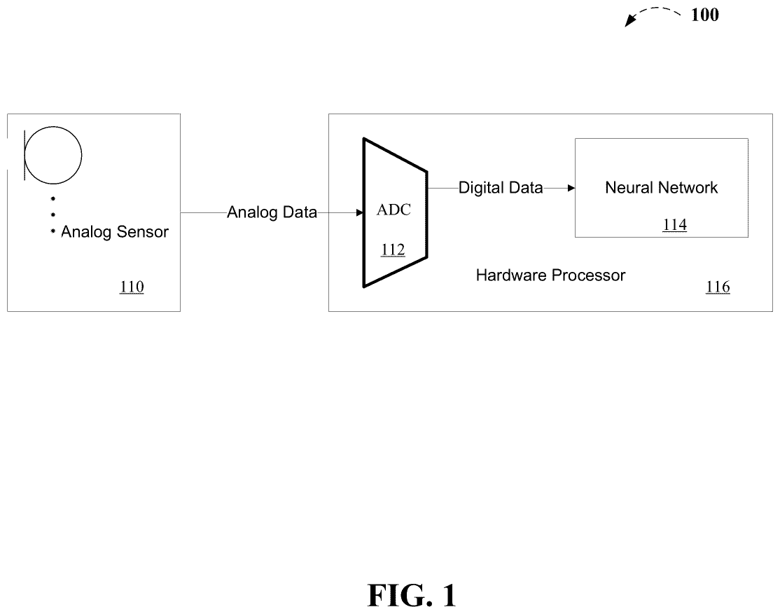

FIG. 1 illustrates an example embodiment of a system that is simulated by using systems and methodologies of the present invention. System 100 includes an analog sensor 110, an analog-to-digital converter (ADC) 112, and a neural network 114. The analog sensor 110 can be a MEMS sensor or a non-MEMS sensor. The analog sensor 110 can be a microphone or a motion sensor, for example, an accelerometer, a gyroscope, or a compass. Sensor 110 can include a combination of multiple sensors. ADC 112 can be a tunable ADC for which the sample rate and resolution are adjustable. The neural network 116 can include a feature extractor and a machine learning model (MLM). The neural network 114 can be implemented on a hardware processor 116 of an integrated circuit chip. The neural network can be designed or made by a customer-manufacturer of a commercial product, for example, a wearable device, a toy, or a speaker. The sensor 110 and the ADC 112 can be made by someone other than the customer-manufacturer. Neural network 116 can be implemented in hardware, software, or firmware.

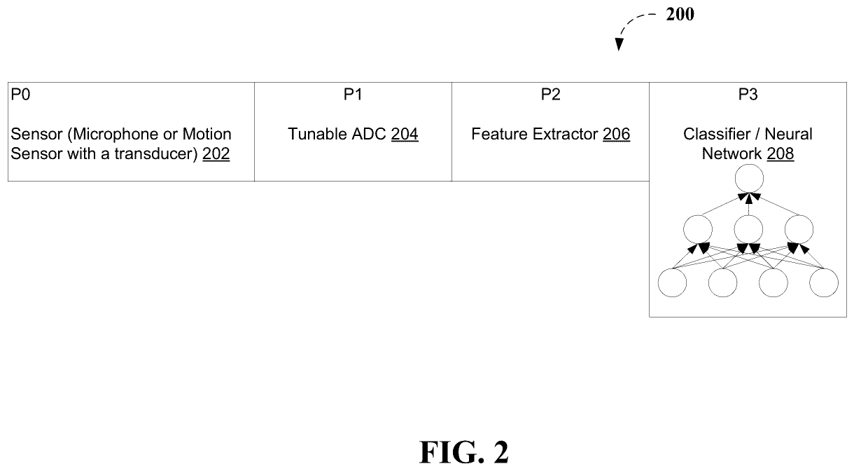

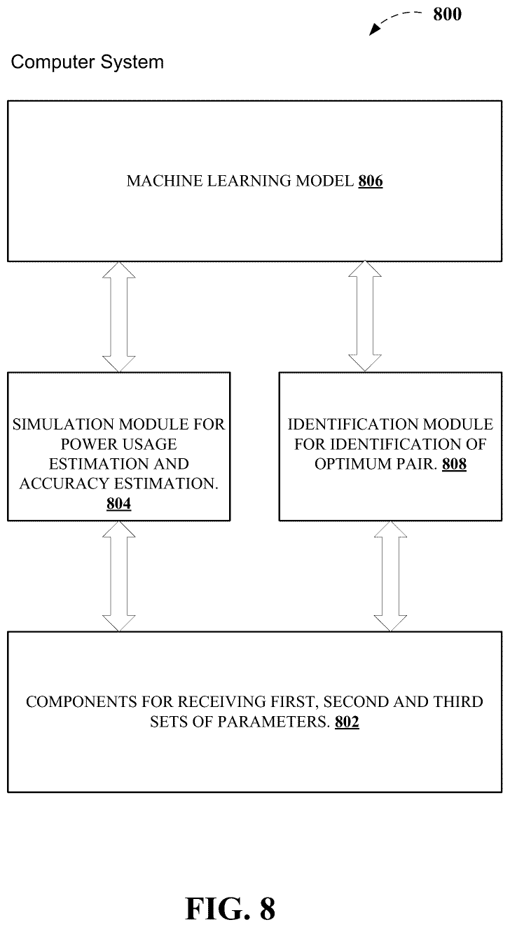

FIG. 2 illustrates an example embodiment power model for the system of FIG. 1. The power model 200 has four components. Power component P0 202 refers to the power usage by sensor 110. This information can be obtained from datasheet(s) of sensor 110 and can be obtained from the Internet. The power usage by sensor 110 can include a range or values and can depend on the mode of operation of sensor 110. Power component P1 204 refers to the power usage by ADC 112. This information can be obtained from the datasheet(s) of ADC 112 and can be obtained from the Internet. The ADC 112 can be tunable, and its resolution and sample rate parameters can be adjustable. The power usage of ADC 112 can depend on the settings of the resolution and sample rate. For example, higher resolution and sample rate values can require higher power usage than lower resolution and sample rate values. Power component P2 206 refers to power usage by the feature extractor of the neural network 114. The feature extractor can be used to identify features of the activity or event detected by sensor 110. Power component P3 208 refers to power usage by the classifier of the neural network 114. The classifier can be used to classify the activity or event detected by sensor 110. Feature extractor and classifier together identify or recognize the event or activity. Feature extractor and classifier can be implemented via a Convolutional Neural Network (CNN). Feature extractor and classifier can be implemented via a Machine Learning Model (MLM). This MLM would be implemented in the neural network 114. This MLM would be a different MLM from the MLM that is used to estimate the performance of the power model 200. The MLM that is used to estimate the performance of the power model 200 does not reside in the commercial electronic product that it simulates. Rather, it resides in a different computer system (see e.g. FIG. 8). This MLM is trained by, for example, simulating different quality ADCs and MEMS sensors. When in use upon completion of the training, this MLM can automatically select the ADC's sample rate/resolution and the MLM size for the MLM that would reside in the commercial product, based on maximum power usage limit or the minimum performance that is required. The MLM that resides in the commercial product is often sensitive to the parameters of other components of the system such as the sensor and the ADC, and its size can vary depending on the parameters.

Power components P0-P3 202, 204, 206, 208 together define the power model 200, meaning power usage for the system 100. In some systems, for example, battery operated wearable devices, it is important to reduce the total power usage 200 of the system 100. In other systems, for example, high end audio speakers, having high accuracy in recognizing the spoken words or utterances is more important than reducing the power usage. In some other systems, finding an optimum pair of accuracy and power usage is important. In this disclosure, the terms optimum and optimal are used interchangeably. The purpose of the power model 200 is to make the system 100 a smart system. For example, a smart microphone system that uses less power, because of the power model based simulations, for recognizing keywords, voice, and sound events. In a smart microphone, the performance of the ADC 112 is decreased for tasks that don't need high quality audio, thus reducing the power used by the ADC 112.

In microphone systems, typically, most of the power consumption comes from the digital microphone, which is a combination of the MEMS microphone sensor and the ADC. Between the sensor and the ADC, a significant part of power consumption is by the ADC. The ADC's power usage grows linearly with sample rate and exponentially with resolution. In one example, P0 and P1 can add up to 560 microwatts of power usage, and P2 and P3 can add up to 140 microwatts of power usage, for a total of 700 microwatts of power usage by the system. In another example, P0 and P1 can add up to 260 microwatts of power usage, and P2 and P3 can add up to 140 microwatts of power usage, for a total of 400 microwatts of power usage by the system. In both examples, the ADC (meaning) used significant power, almost one half the power used by the sensor. In sum, by not wasting unnecessary power on the ADC, the system can save significant power.

Analog sensors are often passive sensors and so the power used by them is not adjustable or only slightly adjustable. However, the ADC offers much opportunity for power saving as its power usage grows linearly with sample rate and exponentially with resolution. The power usage of the feature extractor grows linearly with sample rate. The power usage of the MLM is related to the size of the MLM.

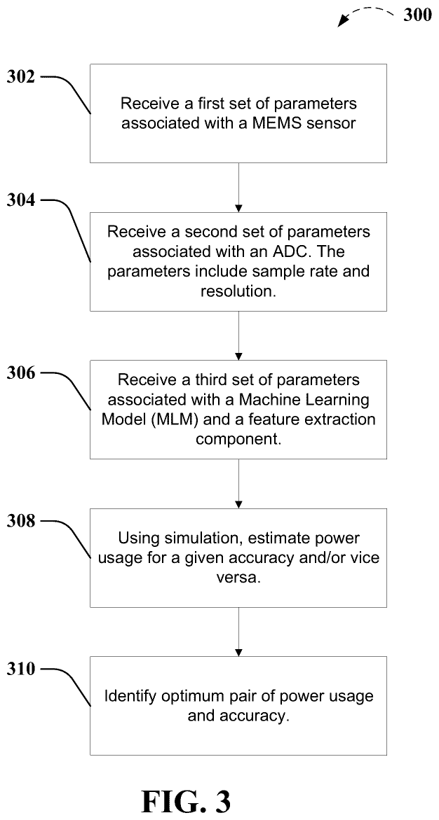

FIG. 3 illustrates an example methodology for simulating the power model. In method 300, at step 302, a first set of parameters associated with the MEMS sensor is received. The parameters can include, for example, voltage and current requirements for the MEMS sensor. Parameter means both the type of parameter (e.g. voltage) and the value(s) of the parameter. At step 304, a second set of parameters associated with the ADC is received. The parameters associated with the ADC include the sample rate and the resolution. At step 306, a third set of parameters associated with the neural network is received. The third set of parameters can include, for example, the size(s) of the neural network. In some examples, the parameters associated with the neural network can be separated into two sets of parameters: one set for the extraction feature module and one for the MLM. In steps 302, 304, 306, data or information can be received automatically or manually. At step 308, the aforementioned information is used to run simulations. In one example, estimated power usage level for a given accuracy level is calculated. This step can be repeated for numerous different accuracy levels. In another example, estimated accuracy level for a given power usage level is calculated. This step can be repeated for numerous different power usage levels. The power usage level can be given for the whole power model 200 or for its individual components 202, 204, 206, 208. At step 310, an optimum pair of power usage and accuracy is identified. In one example, the optimum pair uses the least power for a given accuracy. In another example, the optimum pair is the most accurate for a given power usage. In another example, the optimum pair uses the least power for a particular power model component for a given accuracy. In another example, the optimum pair provides acceptable levels of power usage and accuracy that are neither the least in terms of power usage level nor highest in terms of accuracy level. For example, the optimum pair can be defined to have above-average accuracy and below-average power usage. For another example, the optimum pair can be defined to have average accuracy and average power usage.

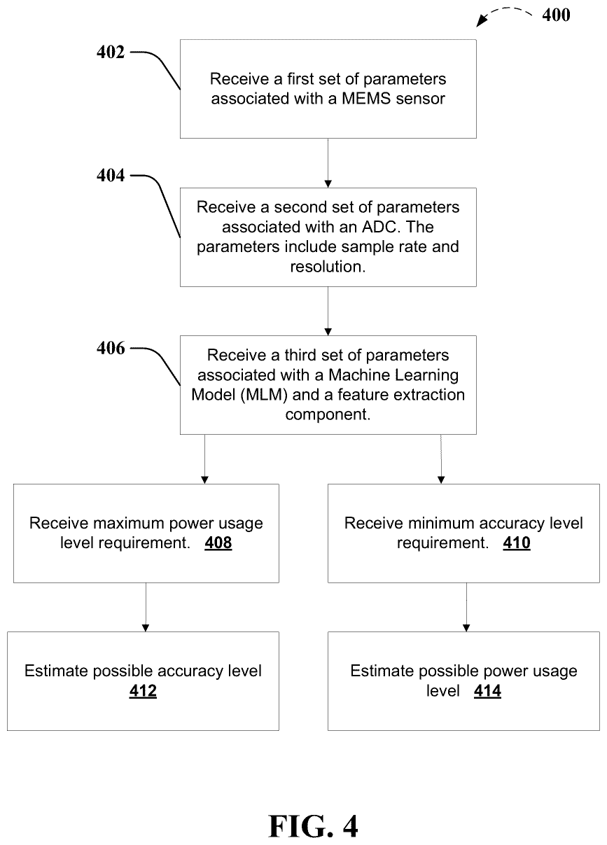

FIG. 4 illustrates another example methodology for simulating the power model. In method 400, at step 402, a first set of parameters associated with the MEMS sensor is received. The parameters can include, for example, voltage and current requirements for the MEMS sensor. Parameter means both the type of parameter (e.g. voltage) and the value(s) of the parameter. At step 404, a second set of parameters associated with the ADC is received. The parameters associated with the ADC include the sample rate and the resolution. At step 406, a third set of parameters associated with the neural network is received. The third set of parameters can include, for example, the size(s) of the neural network. In steps 402, 404, 406, data or information can be received automatically or manually. In the case of automatic, computer components can automatically obtain the information from the Internet. In the case of manually obtained information, a user can enter the information manually via an interactive user interface. A combination of manual and automatic can also be used. For example, a user can manually enter identification of the ADC manufacturer and/or a model number, and then computer components can automatically obtain the parameters from the Internet. At step 408, the maximum allowable or desirable power usage level input is received. The maximum allowable or desired power usage level means that the system must not exceed this power usage level. This input can be manually entered by the user, or it can be automatically received. In response to receiving the input at step 408, at step 412, the estimated possible accuracy level for the desired power usage level is estimated. Alternatively, or in addition to step 408, at step 410, the minimum desired accuracy level input is received. The minimum desired accuracy level means that accuracy must be higher than this level. This input can be manually entered by the user, or it can be automatically received. In response to receiving the input at step 410, at step 414, the estimated power usage level for the desired minimum accuracy level is estimated.

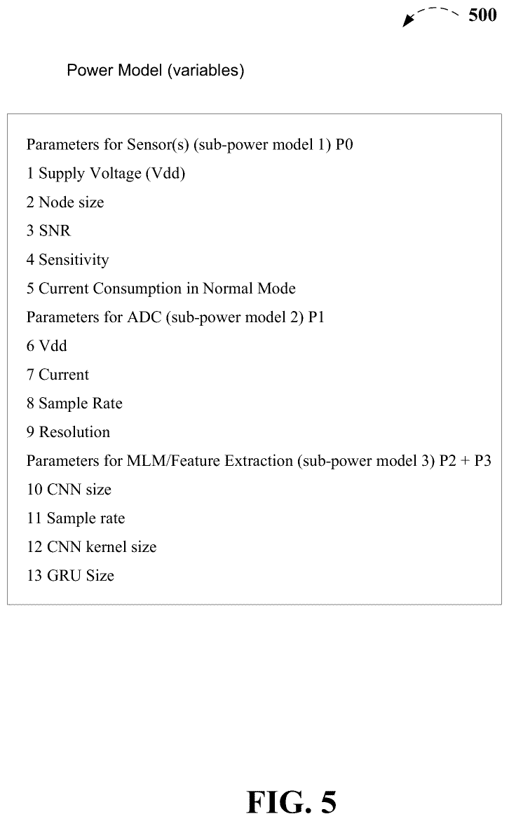

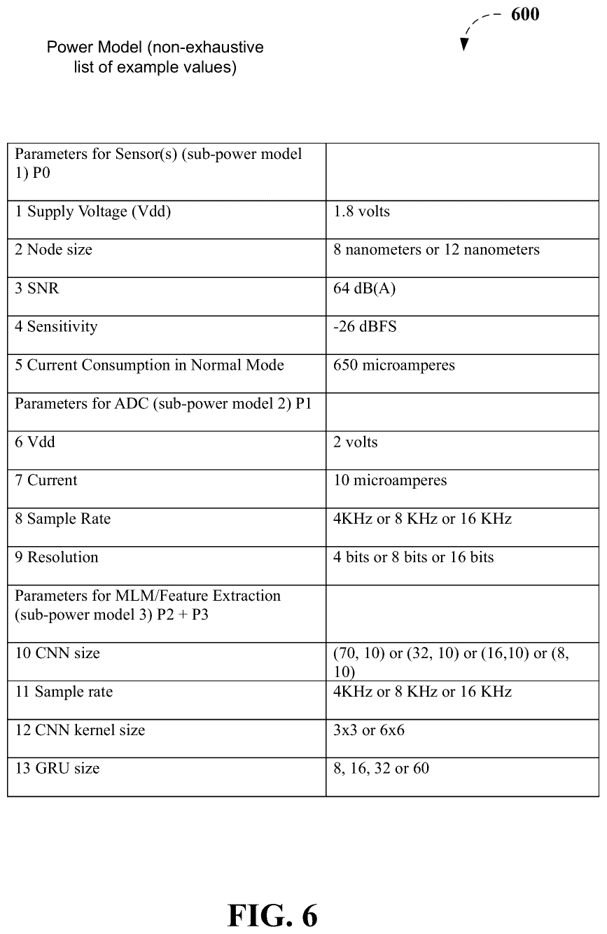

FIG. 5 illustrates an example list of parameters for a power model. The table 500 shown in FIG. 5 shows variables and FIG. 6 shows examples values for those variables. The parameters for sensor 110 are supply voltage, node size, signal-to-noise ratio (SNR), sensitivity, and current consumption in normal mode of operation. The parameters for ADC 112 are supply voltage, current, sample rate and resolution. The parameters for the component including feature extraction component, MLM and neural network (P2 and P3 in FIG. 3) are CNN size, sample rate, CNN kernel size and GRU (Gated Recurrent Unit) size. This table 500 does not present an exhaustive list of parameters and many other parameters are possible.

FIG. 6 illustrates an example list of parameter values for a power model. As shown in table 600, the parameter values for the sensor 110 are 1.8 volts (supply voltage), 5 nanometers (node size), 64 dB (A) (signal-to-noise ratio (SNR)), −26 dBFS (sensitivity), and 60 microamperes (current consumption in normal mode of operation). The parameter values for ADC 112 are 2 volts (supply voltage), 10 microamperes (current), 8 bits (sample rate) and 16 KHz (resolution). The parameter values for the component including feature extraction component, MLM and neural network (P2 and P3 in FIG. 3) are 70 (CNN size), 4 bits (sample rate), (3×3) CNN kernel size and GRU (Gated Recurrent Unit) size. This table 600 only shows one example value for each parameter. Many other parameter values are possible. For example, sample rate can range from 1 KHz (hertz) to 16 KHz (or more) and resolution can range from 4 bits (or less) to 16 bits (or more).

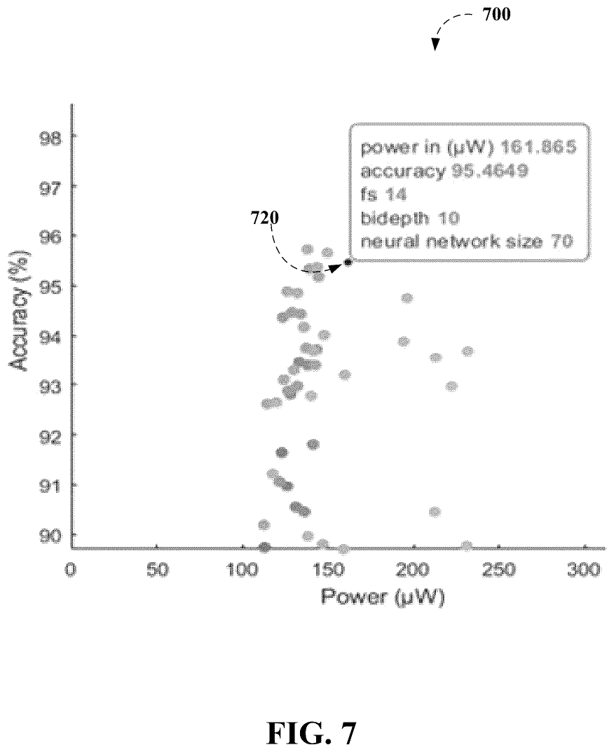

FIG. 7 illustrates an example accuracy-power plot that can result from simulation or the power model. On plot 700, the x-axis shows power usage values ranging from 0 to 300 microwatts. On the y-axis, accuracy is shown ranging from 90 percent accurate to 98 percent accurate. Each dot shown on plot 700 is associated with a pair of values. One value in the pair is the power usage value and the other value is the accuracy value. For example, dot 720 corresponds with a power usage of 161.865 microwatts and 95.4649 percent accuracy. What this means is that for the event or activity that is being simulate, for a specific set of parameter values (ADC sample rate of 14 hertz, ADC resolution of 10 bits, and neural network size of 70), the estimated power usage is 161.865 microwatts estimated accuracy is 95.4649 percent for power model 200. The other dots on plot 700 show the power-accuracy pairs for various other parameter values. The pair represented by dot 720 can be called the optimum pair even though it does not offer maximum accuracy or minimum power. Dot 720 can still represent an optimum pair because it gives excellent accuracy for a reasonable power usage. For example, one of the dots immediately to the left of dot 720 may not represent an optimum pair in a given circumstance because the maximum neural network size requirement associated with that dot is too small. In other words, what is or isn't an optimum pair may depend on the system, the application at hand, and/or the system designer's preferences. For example, simulations may show that total power usage can drop significantly from 500 uW to 250 uW while keeping the performance (meaning accuracy) acceptable. In that case, that would become the optimum point.

FIG. 8 illustrates a sample computer system in which methodologies of the present invention can be implemented. In system 800, component(s) 802 receives parameters for the first, second and third sets of parameters. Components can receive the parameters manually via user input or automatically from a network such as the Internet. User input can be received via an interactive user interface. Simulation module 804 then runs simulations on the data received by component(s) 802. A Machine Learning Model (MLM) 806 can assist with the simulations. The MLM 806 can include a library of trained models that assist with power usage and accuracy estimations. For example, the MLM 806 can contain trained models that were trained by using known parameter data for sensor and ADC products made by known manufacturers. The identification module 808 can then identify the optimum pair, with or without assistance from the MLM 806.

The simulation module 804 also provides values for the estimated system parameters that would be required to meet a given accuracy target. For example, if the target accuracy is 95% accuracy, the simulation module may list the below parameters: Fs=8e3 (8 KHz), ENOB=8 bits, CNNSize=70, and GRUSize=60. Fs refers to sample rate, ENOB refers to resolution, CNNSize refers to size of the CNN network, and GRUSize refers to size of the GRU. For another example, if the target accuracy is 80% accuracy, the simulation module may list the below parameters: Fs=10e3 (10 KHz), ENOB=4 bits, CNNSize=32, and GRUSize=32. A CNN network's size can be defined by a parameters number or one or more parameter numbers, which can be calculated in various ways, for example, by its width, height, and depth, or the number of layers of a CNN, its weights and biases, or by the number of filters used by a CNN, or by the size of the filters. A GRU's size can defined by one or more parameter numbers which can be, for example, function(s) of its input and output dimensions (weights and biases).

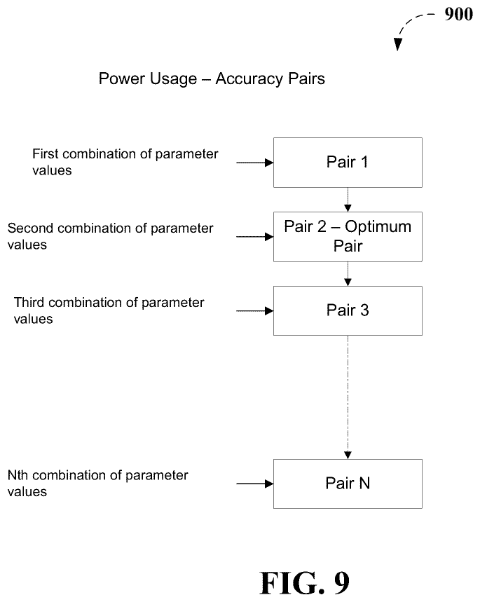

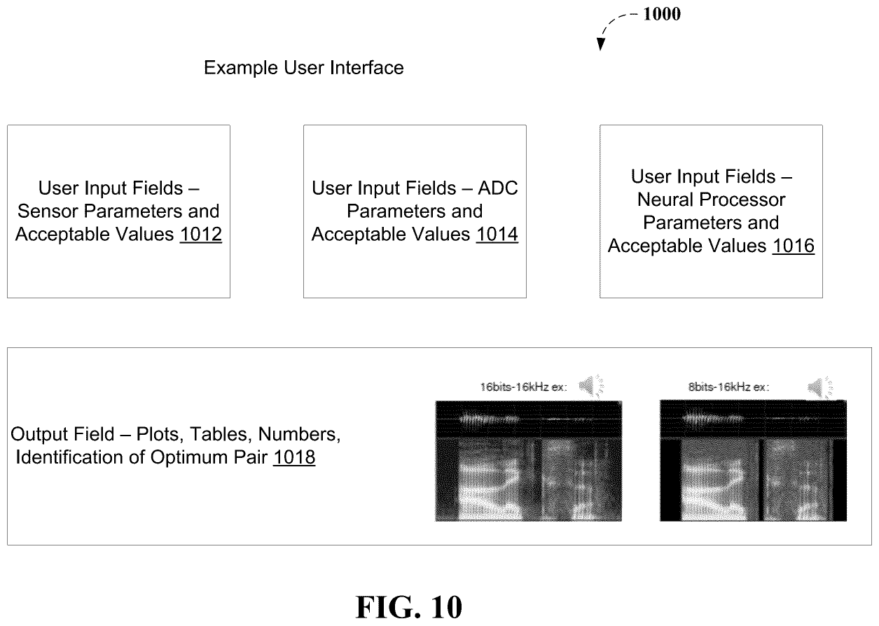

FIG. 9 illustrates example accuracy-power pairs simulated by the simulation module 804. In this example of accuracy-power pairs 900, the simulation module 804 has generated N pairs. In this example, the identification module 808 has selected Pair 2 as the optimum pair. In various examples, the user can be shown all or many of the accuracy-power pairs and the parameter values associated with them, via an interactive user interface, and the user can then select the optimum pair. FIG. 10 illustrates an example interactive user interface. The user can enter parameters in fields 1012, 1014 and 1016, for example, by using a computer keyboard or by using voice commands. The fields 1012, 1014 and 1016 can appear on a computer display screen. The computer display can output information for the user to view and select from 1018. For example, the computer display can show the user the various results of the simulations run on the power model 200. For example, the activity or the event can be a verbal command that is captured by the MEMS microphone 110. The user can then click on various files of the simulated database and hear the captured verbal command that is played back. The user can then select the simulation file that the user desires to be the optimum pair file. In FIG. 10, the computer display would show two audio files from the database in field 1018. One file contains audio captured at the ADC setting of 16 bits/16 KHz. The other file contains audio captures at the ADC setting of 8 bits/16 KHz. These files can be created by using the simulation module 804. A user can play back each file by clicking on it and upon listening to each, these choose one of them as being associated with optimum pair of power usage and accuracy.

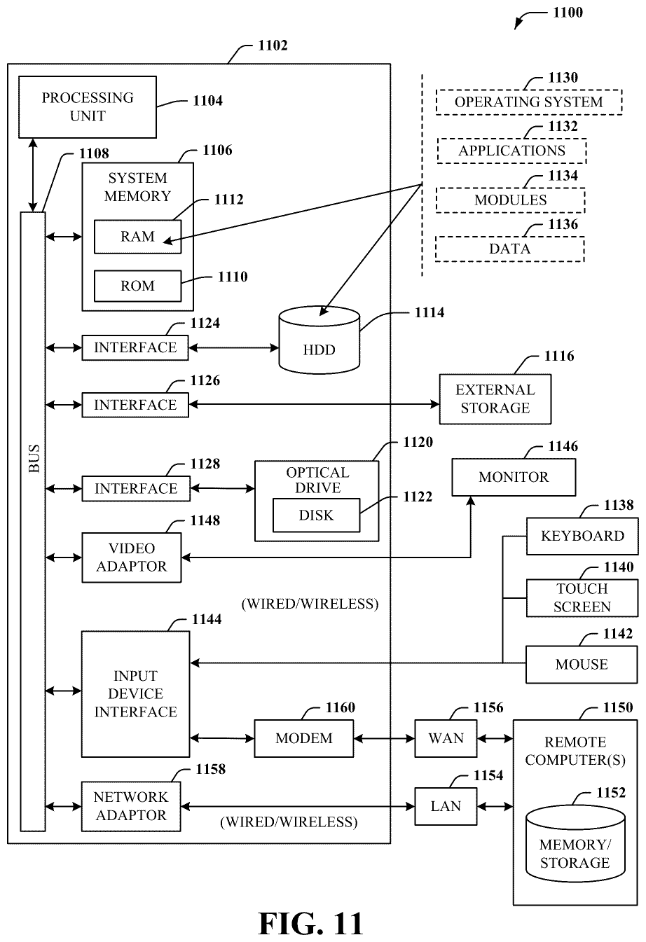

FIG. 11 illustrates a functional block-diagram of an exemplary computing device suitable for practicing various non-limiting aspects described herein. Various components of the computing environment can be implemented in the off-line device, the chip, or the end device having the sensor (motion or microphone). In order to provide additional context for various embodiments described herein, FIG. 11 and the following discussion are intended to provide a brief, general description of a suitable computing environment 1100 in which the various embodiments described herein can be implemented. While the embodiments have been described above in the general context of computer-executable instructions that can run on one or more computers, those skilled in the art will recognize that the embodiments can be also implemented in combination with other program modules and/or as a combination of hardware and software.

Generally, program modules include routines, programs, components, data structures, and related data, that perform particular tasks or implement particular abstract data types. Moreover, those skilled in the art will appreciate that the inventive methods can be practiced with other computer system configurations, including single-processor or multiprocessor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

Some aspects of illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (RAM), read only memory (ROM), electrically erasable programmable read only memory (EEPROM), flash memory or other memory technology, compact disk read only memory (CD-ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 11, the example environment 1100 for implementing various embodiments of the aspects described herein includes a computer 1102, the computer 1102 including a processing unit 1104, a system memory 1106 and a system bus 1108. The system bus 1108 couples system components including, but not limited to, the system memory 1106 to the processing unit 1104. The processing unit 1104 can be any of various commercially available processors. Dual microprocessors and other multi-processor architectures can also be employed as the processing unit 1104. The system memory 1106 can be used to store Machine Learning Models (MLM). The system memory 1106 can also be used to store neural networks, feature extractors, and CNN.

The system bus 1108 can be any of several types of bus structure that can further interconnect to a memory bus (with or without a memory controller), a peripheral bus, and a local bus using any of a variety of commercially available bus architectures. The system memory 1106 includes ROM 1110 and RAM 1112. A basic input/output system (BIOS) can be stored in a non-volatile memory such as ROM, erasable programmable read only memory (EPROM), EEPROM, which BIOS contains the basic routines that help to transfer information between elements within the computer 1102, such as during startup. The RAM 1112 can also include a high-speed RAM such as static RAM for caching data.

The computer 1102 further includes an internal hard disk drive (HDD) 1114 (e.g., EIDE, SATA), one or more external storage devices 1116 (e.g., a magnetic floppy disk drive (FDD) 1116, a memory stick or flash drive reader, a memory card reader, and similar devices) and an optical disk drive 1120 (e.g., which can read or write from a CD-ROM disc, a DVD, a BD, and similar devices). While the internal HDD 1114 is illustrated as located within the computer 1102, the internal HDD 1114 can also be configured for external use in a suitable chassis (not shown). Additionally, while not shown in environment 1100, a solid state drive (SSD) could be used in addition to, or in place of, an HDD 1114. The HDD 1114, external storage device(s) 1116 and optical disk drive 1120 can be connected to the system bus 1108 by an HDD interface 1124, an external storage interface 1126 and an optical drive interface 1128, respectively. The interface 1124 for external drive implementations can include at least one or both of Universal Serial Bus (USB) and Institute of Electrical and Electronics Engineers (IEEE) 1394 interface technologies. Other external drive connection technologies are within contemplation of the embodiments described herein. The HDD 1114 and external storage device(s) 1116 can be used to store information about parameters of various MEMS sensors and ADCs made by known manufacturers of those products.

The drives and their associated computer-readable storage media provide nonvolatile storage of data, data structures, computer-executable instructions, and so forth. For the computer 1102, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1112, including an operating system 1130, one or more application programs 1132, other program modules 1134 and program data 1136. All or portions of the operating system, applications, modules, and/or data can also be cached in the RAM 1112. The systems and methods described herein can be implemented utilizing various commercially available operating systems or combinations of operating systems.

Computer 1102 can optionally comprise emulation technologies. For example, a hypervisor (not shown) or other intermediary can emulate a hardware environment for operating system 1130, and the emulated hardware can optionally be different from the hardware illustrated in FIG. 11. In such an embodiment, operating system 1130 can comprise one virtual machine (VM) of multiple VMs hosted at computer 1102. Furthermore, operating system 1130 can provide runtime environments, such as the Java runtime environment or the .NET framework, for applications 1132. Runtime environments are consistent execution environments that allow applications 1132 to run on any operating system that includes the runtime environment. Similarly, operating system 1130 can support containers, and applications 1132 can be in the form of containers, which are lightweight, standalone, executable packages of software that include, e.g., code, runtime, system tools, system libraries and settings for an application.

Further, computer 1102 can be enable with a security module, such as a trusted processing module (TPM). For instance with a TPM, boot components hash next in time boot components, and wait for a match of results to secured values, before loading a next boot component. This process can take place at any layer in the code execution stack of computer 1102, e.g., applied at the application execution level or at the operating system (OS) kernel level, thereby enabling security at any level of code execution.

A user can enter commands and information into the computer 1102 through one or more wired/wireless input devices, e.g., a keyboard 1138, a touch screen 1140, and a pointing device, such as a mouse 1142. The user can use these interactive tools to enter parameters, view the simulation plot, review the database files created by the simulation, and select the optimum pair. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1104 through an input device interface 1144 that can be coupled to the system bus 1108, but can be connected by other interfaces, such as a parallel port, an IEEE 1394 serial port, a game port, a USB port, an IR interface, a BLUETOOTH® interface, and similar interfaces.

A monitor 1146 or other type of display device can be also connected to the system bus 1108 via an interface, such as a video adapter 1148. In addition to the monitor 1146, a computer typically includes other peripheral output devices (not shown), such as speakers, printers, and similar devices.

The computer 1102 can operate in a networked environment using logical connections via wired and/or wireless communications to one or more remote computers, such as a remote computer(s) 1150. The remote computer(s) 1150 can be a workstation, a server computer, a router, a personal computer, portable computer, microprocessor-based entertainment appliance, a peer device or other common network node, and typically includes many or all of the elements described relative to the computer 1102, although, for purposes of brevity, only a memory/storage device 1152 is illustrated. The logical connections depicted include wired/wireless connectivity to a local area network (LAN) 1154 and/or larger networks, e.g., a wide area network (WAN) 1156. Such LAN and WAN networking environments are commonplace in offices and companies, and facilitate enterprise-wide computer networks, such as intranets, all of which can connect to a global communications network, e.g., the Internet.

When used in a LAN networking environment, the computer 1102 can be connected to the local network 1154 through a wired and/or wireless communication network interface or adapter 1158. The adapter 1258 can facilitate wired or wireless communication to the LAN 1154, which can also include a wireless access point (AP) disposed thereon for communicating with the adapter 1158 in a wireless mode.

When used in a WAN networking environment, the computer 1102 can include a modem 1160 or can be connected to a communications server on the WAN 1156 via other means for establishing communications over the WAN 1156, such as by way of the Internet. The modem 1160, which can be internal or external and a wired or wireless device, can be connected to the system bus 1108 via the input device interface 1144. In a networked environment, program modules depicted relative to the computer 1102 or portions thereof, can be stored in the remote memory/storage device 1152. It will be appreciated that the network connections shown are example and other means of establishing a communications link between the computers can be used.

When used in either a LAN or WAN networking environment, the computer 1102 can access cloud storage systems or other network-based storage systems in addition to, or in place of, external storage devices 1116 as described above. Generally, a connection between the computer 1102 and a cloud storage system can be established over a LAN 1154 or WAN 1156 e.g., by the adapter 1158 or modem 1160, respectively. Upon connecting the computer 1102 to an associated cloud storage system, the external storage interface 1126 can, with the aid of the adapter 1158 and/or modem 1160, manage storage provided by the cloud storage system as it would other types of external storage. For instance, the external storage interface 1126 can be configured to provide access to cloud storage sources as if those sources were physically connected to the computer 1102.

The computer 1102 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, bin), and telephone. This can include Wireless Fidelity (Wi-Fi) and BLUETOOTH® wireless technologies. Thus, the communication can be a predefined structure as with a conventional network or simply an ad hoc communication between at least two devices.

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure for illustrative purposes, various modifications are possible that are considered within the scope of such embodiments and examples, as those skilled in the relevant art can recognize.

As used in this application, the terms “component,” “module,” “device” and “system” are intended to refer to a computer-related entity, either hardware, a combination of hardware and software, software, or software in execution. As one example, a component or module can be, but is not limited to being, a process running on a processor, a processor or portion thereof, a hard disk drive, multiple storage drives (of optical and/or magnetic storage medium), an object, an executable, a thread of execution, a program, and/or a computer. By way of illustration, both an application running on a server and the server can be a component or module. One or more components or modules scan reside within a process and/or thread of execution, and a component or module can be localized on one computer or processor and/or distributed between two or more computers or processors.

As used herein, the term to “infer” or “inference” refer generally to the process of reasoning about or inferring states of the system, and/or environment from a set of observations as captured via events, signals, and/or data. Inference can be employed to identify a specific context or action, or can generate a probability distribution over states, for example. The inference can be probabilistic—that is, the computation of a probability distribution over states of interest based on a consideration of data and events. Inference can also refer to techniques employed for composing higher-level events from a set of events and/or data. Such inference results in the construction of new events or actions from a set of observed events and/or stored event data, whether or not the events are correlated in close temporal proximity, and whether the events and data come from one or several event and data sources.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word, “exemplary,” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A computer system, comprising:
a first component for receiving as input a first set of parameters associated with a MEMS sensor configured to collect analog data associated with an event or an activity and possible values for each parameter of the first set of parameters;
a second component for receiving as input a second set of parameters associated with an analog-to-digital converter (ADC) configured to convert the analog data into digital data and possible values for each parameter of the second set of parameters, wherein the second set of parameters includes sample rate and resolution;
a third component for receiving as input a third set of parameters associated with an integrated circuit chip including a feature extraction module and a machine learning model (MLM) configured to recognize the event or the activity by using the digital data and possible values for each parameter of the third set of parameters;
a simulation module configured to estimate power usage value and accuracy value based on the three sets of parameters using a MLM; and
an identification module to determine one of a maximum estimated accuracy value and information for associated parameters for a given maximum power usage target value or a minimum power usage value and information for associated parameters for a given minimum accuracy target value.

2. The computer system of claim 1, further comprising: the simulation module for simulating one of a wearable device, a toy, or a speaker.

3. The computer system of claim 1, wherein the MEMS sensor is one of a microphone or a motion sensor.

4. The computer system of claim 1, wherein the event or the activity includes one of a movement or utterance of a keyword, voice, alarm or a sound.

5. The computer system of claim 1, further comprising: the identification module is configured to identify a best pair of accuracy value and power usage value, wherein the identification includes identifying information for associated parameters for an optimum combination of accuracy and power usage.

6. The computer system of claim 1, further comprising: the simulation module is configured to separately estimate power usage values for each of the MEMS sensor, the ADC, and the integrated circuit chip.

7. The computer system of claim 1, wherein the first, second, and third components are configured to perform the receiving of the first, second, and third sets of parameters and their respective possible values one of automatically or manually.

8. A method, comprising:
receiving as input a first set of parameters associated with a MEMS sensor configured to collect analog data associated with an event or an activity and possible values for each parameter of the first set of parameters;
receiving as input a second set of parameters associated with an analog-to-digital converter (ADC) configured to convert the analog data into digital data and possible values for each parameter of the second set of parameters, wherein the second set of parameters includes sample rate and resolution;
receiving as input a third set of parameters associated with an integrated circuit chip including a feature extraction module and a machine learning model (MLM) configured to recognize the event or the activity by using the digital data and possible values for each parameter of the third set of parameters;
using simulation to estimate power usage value and accuracy value based on the three sets of parameters and the MLM; and
determining one of a maximum estimated accuracy value and information for associated parameters for a given maximum power usage target value or a minimum power usage value and information for associated parameters for a given minimum accuracy target value.

9. The method of claim 8, further comprising: using simulation to simulate one of a wearable device, a toy, or a speaker.

10. The method of claim 8, wherein the MEMS sensor is one of a microphone or a motion sensor.

11. The method of claim 8, wherein the event or the activity includes one of a movement or utterance of a keyword, voice, alarm or a sound.

12. The method of claim 8, further comprising: identifying a best pair of accuracy value and power usage value, wherein the identification includes identifying information for associated parameters for an optimum combination of accuracy and power usage.

13. The method of claim 8, further comprising: using simulation to separately estimate power usage values for each of the MEMS sensor, the ADC, and the integrated circuit chip.

14. The method of claim 8, wherein receiving the first, second, and third sets of parameters and their respective possible values one of automatically or manually.

15. A computer system, comprising:
a Machine Learning Model (MLM) trained to facilitate simulations to estimate power usage value and accuracy value upon receiving the below information
a first set of parameters associated with a MEMS sensor configured to collect analog data associated with an event or an activity and possible values for each parameter of the first set of parameters;
a second set of parameters associated with an analog-to-digital converter (ADC) configured to convert the analog data into digital data and possible values for each parameter of the second set of parameters, wherein the second set of parameters includes sample rate and resolution; and
a third set of parameters associated with the integrated circuit chip including a feature extraction module and a neural network configured to recognize the event or the activity by using the digital data and possible values for each parameter of the third set of parameters; wherein,
the first and second set of parameters for creating a new database; and
the third set of parameters for training a new MLM.

16. The computer system of claim 15, further comprising: the MLM is trained to facilitate identification of a maximum estimated accuracy value and information for associated parameters for a given maximum power usage target value or minimum power usage value and information for associated parameters for a given minimum accuracy target value.

17. The computer system of claim 15, wherein the MEMS sensor is one of a microphone or a motion sensor.

18. The computer system of claim 15, wherein the event or the activity includes one of a movement or utterance of a keyword, voice, alarm or a sound.

19. The computer system of claim 15, further comprising: the MLM is trained to facilitate separate estimations of power usage values for each of the MEMS sensor, the ADC, and the integrated circuit chip.

20. The computer system of claim 15, further comprising: the MLM is trained to facilitate simulations for one of a wearable device, a toy, or a speaker.
